(19) United States
(12) Patent Application Publication
(10) Pub. No.: US 2023/0179170 A1
(43) Pub. Date: Jun. 8, 2023

(54) ACOUSTIC WAVE RESONATOR PACKAGE

(71) Applicant: SAMSUNG ELECTRO-MECHANICS CO., LTD., Suwon-si (KR)

(72) Inventors: Seung Wook PARK, Suwon-si (KR); Seong Hun NA, Suwon-si (KR); Jae Hyun JUNG, Suwon-si (KR); Sung HAN, Suwon-si (KR); Jang Ho PARK, Suwon-si (KR)

(73) Assignee: SAMSUNG ELECTRO-MECHANICS CO., LTD., Suwon-si (KR)

(21) Appl. No.: 17/859,534

(22) Filed: Jul. 7, 2022

(30) Foreign Application Priority Data
Dec. 3, 2021 (KR) 10-2021-0172276

(51) Int. Cl. H03H 9/10; H03H 3/02; H03H 9/17

(52) U.S. Cl. CPC H03H 9/105; H03H 3/02; H03H 9/173; H03H 2003/021

(57) ABSTRACT

An acoustic wave resonator package includes an acoustic resonator comprising an acoustic wave generator on a surface of a substrate, a cover member disposed over the acoustic wave generator, a bonding member, disposed between the substrate and the cover member, to bond the substrate and the cover member to each other, and a wiring layer, disposed along surfaces of the cover member, connected to the acoustic resonator. Among the surfaces of the cover member, bonding surfaces to which the bonding member and the wiring layer are bonded at least partially have a roughness Rz in a range of 70 nm to 3.5 µm.

### CROSS-REFERENCE TO RELATED APPLICATION(S)

This application claims the benefit under 35 USC 119(a) of Korean Patent Application No. 10-2021-0172276 filed on Dec. 3, 2021 in the Korean Intellectual Property Office, the entire disclosure of which is incorporated herein by reference for all purposes.

### BACKGROUND

### 1. Field

The present disclosure relates to an acoustic wave resonator package.

### 2. Description of Related Art

High-frequency components are desired when reducing the size of wireless communications devices. As an example, a bulk acoustic wave (BAW) resonator type filter or a surface acoustic wave (SAW) resonator type filter using semiconductor thin film wafer manufacturing technology may be used in wireless communications devices.

The BAW resonator refers to a thin film type element implemented as a filter, generating resonance using piezoelectric characteristics of a piezoelectric dielectric material deposited on a silicon wafer, a semiconductor substrate. In addition, the SAW resonator refers to a thin film type element implemented as a filter, generating resonance using surface acoustic wave characteristics caused by depositing interdigitated (IDT) electrodes on a lithium tantalate (LT) wafer or a lithium niobate (LN) wafer, which is a piezoelectric substrate. Acoustic resonators that can be implemented within a candidate band and easier to manufacture at a reduced cost are desired in 5G communications technology.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an acoustic wave resonator package includes an acoustic resonator comprising an acoustic wave generator on a surface of a substrate, a cover member disposed over the acoustic wave generator, a bonding member, disposed between the substrate and the cover member, to bond the substrate and the cover member to each other, and a wiring layer, disposed along surfaces of the cover member, connected to the acoustic resonator. Among the surfaces of the cover member, bonding surfaces to which the bonding member and the wiring layer are bonded at least partially have a roughness Rz in a range of 70 nm to 3.5 µm.

The cover member may include a core layer, including glass fibers, and a resin layer disposed on either one or both opposing surfaces of the core layer.

The cover member may include a filler in the resin layer, and a coefficient of thermal expansion of the filler may be lower than a coefficient of thermal expansion of the resin layer.

The filler may be formed of an alumina or silica material.

A side surface of the cover member may be inclined at an acute angle with a lower surface of the cover member.

The wiring layer may be disposed along the side surface and an upper surface of the cover member.

The acoustic wave resonator package may further include an external electrode formed on the wiring layer disposed on the upper surface of the cover member.

The acoustic wave resonator package may further include a through via penetrating through the cover member. One end of the through via may electrically connected to the acoustic resonator.

The acoustic wave resonator package may further include a passive element, disposed on a surface of the cover member, connected to the through via.

The passive element may be formed by patterning a partial portion of the wiring layer.

The acoustic wave resonator package may further include a support member disposed between the cover member and the acoustic resonator. The through via may be connected to the acoustic resonator by penetrating through the support member.

In another general aspect, a method of manufacturing an acoustic wave resonator package, the method includes preparing a panel member including resin layers disposed on opposing surfaces of a core layer, and metal layers stacked on surfaces of the resin layers, partially removing the metal layers from the panel member and increasing surface roughness of the panel member, bonding the panel member to an acoustic resonator using a bonding member, and forming a wiring layer on a surface of the panel member.

The metal layers may be removed through an etching process.

The method may further include cutting the panel member to form a cover member, after the bonding of the panel member to the acoustic resonator using the bonding member. A side surface of the cover member may be formed as an inclined surface during the cutting of the panel member.

The method may further include forming a through-hole in the panel member, before the forming of the wiring layer. The forming of the wiring layer may include filling the through-hole with a conductive material.

The forming of the wiring layer may further include patterning a partial portion of the wiring layer to form a passive element.

The surface roughness of the panel member may be increased to a range between 70 nm to 3.5 µm.

Other features and aspects will be apparent from the following detailed description, the drawings, and the claims.

### BRIEF DESCRIPTION OF DRAWINGS

FIG. 1 is a plan view of an example of an acoustic resonator according to one or more embodiments of the present disclosure.

FIG. 2 is a cross-sectional view taken along line I-I′ of FIG. 1.

FIG. 3 is a cross-sectional view taken along line II-II′ of FIG. 1.

FIG. 4 is a cross-sectional view taken along line III-III′ of FIG. 1.

FIG. 5 is a schematic cross-sectional view illustrating an example of an acoustic wave resonator package according to one or more embodiments of the present disclosure.

FIG. 6 is a view for explaining a method of manufacturing the acoustic wave resonator package illustrated in FIG. 5.

FIG. 7 is a schematic cross-sectional view illustrating another example of an acoustic wave resonator package according to one or more embodiments of the present disclosure.

FIG. 8 is a schematic cross-sectional view illustrating another example of an acoustic wave resonator package according to one or more embodiments of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element’s relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

One or more aspects of the present disclosure may provide an acoustic wave resonator package that is easy to manufacture.

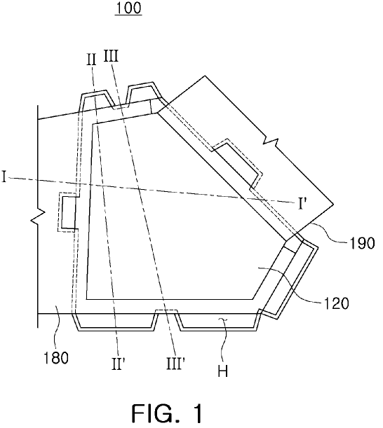

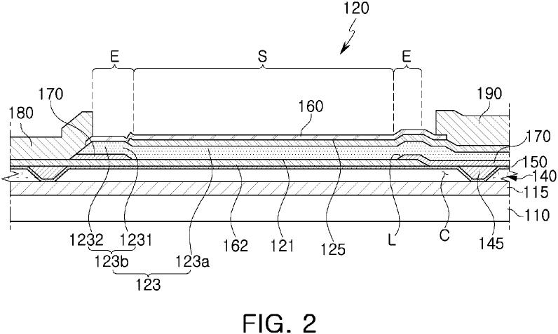

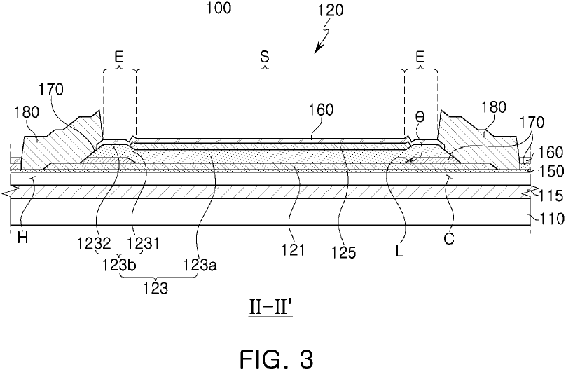

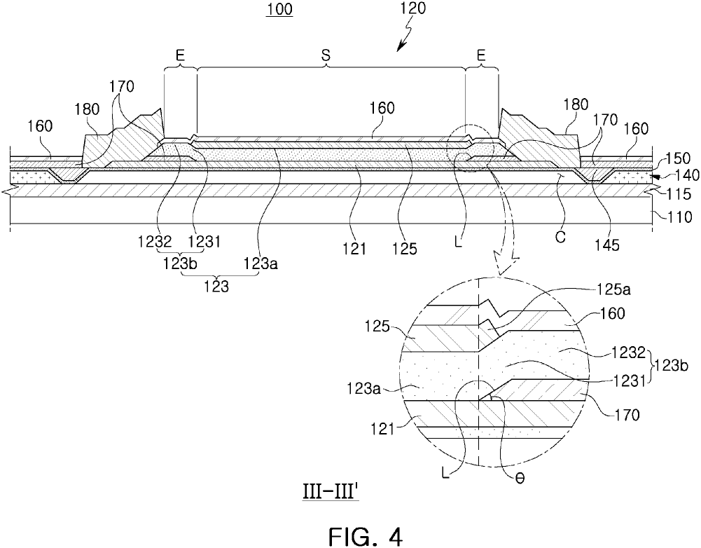

FIG. 1 is a plan view of an example of an acoustic resonator according to one or more embodiments of the present disclosure; FIG. 2 is a cross-sectional view taken along line I-I′ of FIG. 1, FIG. 3 is a cross-sectional view taken along line II-II′ of FIG. 1; and FIG. 4 is a cross-sectional view taken along line III-III′ of FIG. 1.

Referring to FIGS. 1 through 4, an acoustic resonator 100, according to one or more embodiments, may be a bulk acoustic wave (BAW) resonator, and may include a substrate 110, an insulating layer 115, and a resonating unit 120.

The substrate 110 may be a silicon substrate. For example, a silicon wafer or a silicon-on-insulator (SOI) type substrate may be used as the substrate 110.

An insulating layer 115 may be provided on an upper surface of the substrate 110 to electrically isolate the substrate 110 and the resonating unit 120 from each other. In addition, the insulating layer 115 may prevent the substrate 110 from being etched by an etching gas when forming a cavity C during the manufacturing process of the acoustic resonator.

In this case, the insulating layer 115 may be formed of at least one of silicon dioxide (SiO₂), silicon nitride (Si₃N₄), aluminum oxide (Al₂O₃), and aluminum nitride (AIN), and may be formed by any one of a chemical vapor deposition process, a radio frequency (RF) magnetron sputtering process, and an evaporation process.

On the other hand, when the acoustic resonator 100 according to one or more embodiments is a surface acoustic wave (SAW) resonator, the substrate 110 may be a piezoelectric substrate bonded to a lithium tantalate (LT) wafer, a lithium niobate (LN) wafer, or an SOI.

A support layer 140 may be formed on the insulating layer 115, and may be disposed around a cavity C and an etching preventing portion 145 to surround the cavity C and the etching preventing portion 145 inside the support layer 140.

The cavity C may be formed as a space. The cavity C may be formed by removing a partial portion of a sacrificial layer formed in the process of preparing the support layer 140, and the support layer 140 may be formed by the remaining portion of the sacrificial layer.

The support layer 140 may be formed using a material that is easily etched, such as poly-silicon or polymer. However, the support layer 140 is not limited thereto.

The etching preventing portion 145 may be disposed along a boundary of the cavity C. The etching preventing portion 145 may be provided to prevent etching from being performed beyond a cavity region in a process of forming the cavity C.

A membrane layer 150 may be formed on the support layer 140, and may form an upper surface of the cavity C. Therefore, the membrane layer 150 may also be formed of a material that is not easily removed in the process of forming the cavity C.

For example, when a halide-based etching gas such as fluorine (F) or chlorine (Cl) is used to remove a partial portion (e.g., the cavity region) of the support layer 140, the membrane layer 150 may be formed of a material having low reactivity to the aforementioned etching gas. In this case, the membrane layer 150 may include either one or both of silicon dioxide (SiO₂) and silicon nitride (Si₃N₄).

In addition, the membrane layer 150 may be a dielectric layer containing any one or any combination of any two or more of magnesium oxide (MgO), zirconium oxide (ZrO₂), aluminum nitride (AIN), lead zirconate titanate (PZT), gallium arsenide (GaAs), hafnium oxide (HfO₂), aluminum oxide (Al₂O₃), titanium oxide (TiO₂), and zinc oxide (ZnO), or may be a metal layer containing at least one of aluminum (Al), nickel (Ni), chromium (Cr), platinum (Pt), gallium (Ga), and hafnium (Hf). However, according to the present disclosure, the membrane layer 150 is not limited thereto.

The resonating unit 120 may include a first electrode 121, a piezoelectric layer 123, and a second electrode 125. In the resonating unit 120, the first electrode 121, the piezoelectric layer 123, and the second electrode 125 may be sequentially stacked from below. Therefore, in the resonating unit 120, the piezoelectric layer 123 may be disposed between the first electrode 121 and the second electrode 125.

The resonating unit 120 may be formed on the membrane layer 150, and eventually, the resonating unit 120 may be formed by sequentially stacking the membrane layer 150, the first electrode 121, the piezoelectric layer 123, and the second electrode 125 on the substrate 110.

The resonating unit 120 may resonate the piezoelectric layer 123 according to signals applied to the first electrode 121 and the second electrode 125 to generate a resonant frequency and an anti-resonant frequency.

The resonating unit 120 may be divided into a central portion S in which the first electrode 121, the piezoelectric layer 123, and the second electrode 125 are stacked in an approximately flat manner and an extension portion E in which an insertion layer 170 is interposed between the first electrode 121 and the piezoelectric layer 123.

The central portion S may be a region disposed at the center of the resonating unit 120, and the extension portion E may be a region disposed along a circumference of the central portion S. Therefore, the extension portion E, which is a region extending outwardly from the central portion S, may refer to a region formed in a continuous ring shape along the circumference of the central portion S. Alternatively, the extension portion E may be formed in a discontinuous ring shape such that some regions thereof are disconnected if desired.

Therefore, as illustrated in FIG. 2, in a cross section of the resonating unit 120 cut across the central portion S, the extension portion E may be disposed at both ends of the central portion S. In addition, the insertion layer 170 may be disposed on both sides of the extension portion E disposed at both ends of the central portion S.

The insertion layer 170 may have an inclined surface L to have a larger thickness as being farther away from the central portion S.

In the extension portion E, the piezoelectric layer 123 and the second electrode 125 may be disposed on the insertion layer 170. Accordingly, the piezoelectric layer 123 and the second electrode 125 positioned in the extension portion E may have inclined surfaces according to the shape of the insertion layer 170.

Meanwhile, in one or more embodiments, the extension portion E may be defined as being included in the resonating unit 120, and thus, resonance may also be generated in the extension portion E. However, the position at which the resonance is generated is not limited thereto, and resonance may be generated only in the central portion S while resonance is not generated in the extension portion E according to a structure of the extension portion E.

Each of the first electrode 121 and the second electrode 125 may be formed of a conductor, e.g., a metal including at least one of gold, molybdenum, ruthenium, iridium, aluminum, platinum, titanium, tungsten, palladium, tantalum, chromium, and nickel, but is not limited thereto.

In the resonating unit 120, the first electrode 121 may be formed to have a larger area than the second electrode 125, and a first metal layer 180 may be disposed along an outer side of the first electrode 121 on the first electrode 121. Therefore, the first metal layer 180 may be disposed to be spaced apart from the second electrode 125 by a predetermined distance, and may be disposed to surround the resonating unit 120.

The first electrode 121, which is disposed on the membrane layer 150, may be entirely flat. On the other hand, the second electrode 125, which is disposed on the piezoelectric layer 123, may be bent to correspond to the shape of the piezoelectric layer 123.

The first electrode 121 may be used as either an input electrode or an output electrode that inputs or outputs an electrical signal such as an RF signal.

The second electrode 125 may be entirely disposed in the central portion S, and partially disposed in the extension portion E. Thus, the second electrode 125 may be divided into a portion disposed on a piezoelectric portion 123a of the piezoelectric layer 123, which will be described below, and a portion disposed on a bent portion 123b of the piezoelectric layer 123.

More specifically, in one or more embodiments, the second electrode 125 may be disposed to cover an entire portion of the piezoelectric portion 123a and a partial portion of an inclined portion 1231 of the piezoelectric layer 123. Therefore, a second electrode 125a (see FIG. 4) disposed in the extension portion E may have a smaller area than an inclined surface of the inclined portion 1231, and the second electrode 125 may have a smaller area than the piezoelectric layer 123 in the resonating unit 120.

Therefore, as illustrated in FIG. 2, in the cross section of the resonating unit 120 cut across the central portion S, a distal end of the second electrode 125 may be disposed in the extension portion E. In addition, the distal end of the second electrode 125 disposed in the extension portion E may be disposed so that at least a portion thereof overlaps the insertion layer 170. Here, the term “overlap” means that when the second electrode 125 is projected on a plane on which the insertion layer 170 is disposed, a shape of the second electrode 125 projected on the plane overlaps the insertion layer 170.

The second electrode 125 may be used as either an input electrode or an output electrode that inputs or outputs an electrical signal such as an RF signal. That is, when the first electrode 121 is used as the input electrode, the second electrode 125 may be used as the output electrode, and when the first electrode 121 is used as the output electrode, the second electrode 125 may be used as the input electrode.

Meanwhile, as illustrated in FIG. 4, when the distal end of the second electrode 125 is positioned on the inclined portion 1231 of the piezoelectric layer 123, which will be described below, the resonating unit 120 may locally form acoustic impedance in a sparse/dense/sparse/dense structure from the central portion S, thereby increasing a reflection interface reflecting lateral waves inwardly of the resonating unit 120. Therefore, most of the lateral waves may be reflected inwardly of the resonating unit 120 without escaping outwardly of the resonating unit 120, thereby improving the performance of the acoustic resonator.

The piezoelectric layer 123 may generate a piezoelectric effect by converting electrical energy into mechanical energy having an elastic waveform, and may be formed on the first electrode 121 and the insertion layer 170, which will be described below.

As a material of the piezoelectric layer 123, zinc oxide (ZnO), aluminum nitride (AIN), doped aluminum nitride, lead zirconate titanate, quartz, or the like may be selectively used. When the doped aluminum nitride is used, the piezoelectric layer 123 may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

The piezoelectric layer 123, according to one or more embodiments, may include a piezoelectric portion 123a disposed in the central portion S and a bent portion 123b disposed in the extension portion E.

The piezoelectric portion 123a may be a portion stacked directly on the upper surface of the first electrode 121. Therefore, the piezoelectric portion 123aa may be interposed between the first electrode 121 and the second electrode 125, and formed to be flat together with the first electrode 121 and the second electrode 125.

The bent portion 123b may be defined as a region extending outwardly from the piezoelectric portion 123a and positioned in the extension portion E.

The bent portion 123b may be disposed on the insertion layer 170, which will be described below, and may have a raised upper surface according to the shape of the insertion layer 170. Therefore, the piezoelectric layer 123 may be bent at a boundary between the piezoelectric portion 123a and the bent portion 123b, and the bent portion 123b may be raised according to the thickness and the shape of the insertion layer 170.

The bent portion 123b may be divided into an inclined portion 1231 and an extending portion 1232. The inclined portion 1231 may refer to a portion inclined along the inclined surface L of the insertion layer 170, described below. In addition, the extending portion 1232 may refer to a portion extending outwardly from the inclined portion 1231.

The inclined portion 1231 may be formed in parallel with the inclined surface L of the insertion layer 170, and the inclined portion 1231 may have the same inclination angle as the inclined surface L of the insertion layer 170.

The insertion layer 170 may be disposed along a surface formed by the membrane layer 150, the first electrode 121, and the etching preventing portion 145. The insertion layer 170 may be partially disposed in the resonating unit 120, and may be disposed between the first electrode 121 and the piezoelectric layer 123.

The insertion layer 170 may be disposed around the central portion S to support the bent portion 123b of the piezoelectric layer 123. Accordingly, the bent portion 123b of the piezoelectric layer 123 may be divided into an inclined portion 1231 and an extending portion 1232 according to the shape of the insertion layer 170.

In one or more embodiments, the insertion layer 170 may be disposed in a region except for the central portion S. For example, the insertion layer 170 may be disposed in an entire portion or a partial portion (e.g., the extending portion) of the region except for the central portion S on the substrate 110.

The insertion layer 170 may be formed to have a larger thickness as being farther away from the central portion S. Therefore, a side surface of the insertion layer 170 disposed adjacent to the central portion S may be formed as an inclined surface L having a predetermined inclination angle θ.

In order to manufacture the insertion layer 170 having a side surface whose inclination angle θ is smaller than 5°, the thickness of the insertion layer 170 needs to be very small or the area of the inclined surface L of the insertion layer 170 needs to be excessively large, which is substantially difficult to implement.

On the other hand, when the inclination angle θ of the side surface of the insertion layer 170 is greater than 70°, the piezoelectric layer 123 or the second electrode 125 stacked on the insertion layer 170 may also have an inclination angle of greater than 70°. In this case, the piezoelectric layer 123 or the second electrode 125 stacked on the inclined surface L may be excessively bent, thereby causing a crack at the bent portion.

Therefore, in one or more embodiments, the inclination angle θ of the inclined surface L may be in a range of 5° to 70°.

Meanwhile, in one or more embodiments, the inclined portion 1231 of the piezoelectric layer 123 may be formed along the inclined surface L of the insertion layer 170, and may thus be formed at the same inclination angle as the inclined surface L of the insertion layer 170. Therefore, the inclination angle of the inclination portion 1231 may also be in a range of 5° to 70°, similar to that of the inclined surface L of the insertion layer 170. Such a configuration may also be identically applied to the second electrode 125 stacked on the inclined surface L of the insertion layer 170.

The insertion layer 170 may be formed of a dielectric material such as silicon oxide (SiO₂), aluminum nitride (AIN), aluminum oxide (AI₂O₃), silicon nitride (Si₃N₄), magnesium oxide (MgO), zirconium oxide (ZrO₂),lead zirconate titanate (PZT), gallium arsenide (GaAs), hafnium oxide (HfO₂), titanium oxide (TiO₂), or zinc oxide (ZnO), and may be formed of a material different from that of the piezoelectric layer 123.

Alternatively, the insertion layer 170 may be formed of a metal material. For example, when the acoustic resonator, according to one or more embodiments, is used for 5G communications, a large amount of heat may be generated from the resonant unit, and thus, the heat generated from the resonating unit 120 needs to be smoothly dissipated. To this end, the insertion layer 170, according to one or more embodiments, may be formed of an aluminum alloy material containing scandium (Sc).

The resonating unit 120 may be disposed to be spaced apart from the substrate 110 through the cavity C formed as an empty space.

The cavity C may be formed by supplying an etching gas (or an etchant) to introduction holes H (see FIG. 1) in the process of manufacturing the acoustic resonator to remove a partial portion of the support layer 140.

Thus, the cavity C may be formed as a space in which an upper surface (ceiling surface) and a side surface (wall surface) are defined by the membrane layer 150, and a bottom surface is defined by the substrate 110 or the insulating layer 115. Meanwhile, the membrane layer 150 may be formed only on an upper surface (ceiling surface) of the cavity C according to a manufacturing method.

A protective layer 160 may be disposed along a surface of the acoustic resonator 100 to prevent the acoustic resonator 100 from external impact. The protective layer 160 may be disposed along a surface formed by the second electrode 125 and the bent portion 123b of the piezoelectric layer 123.

In addition, the protective layer 160 may be partially removed to control a frequency in the final process for manufacturing the acoustic resonator. For example, a thickness of the protective layer 160 may be controlled in a frequency trimming process for manufacturing the acoustic resonator.

To this end, the protective layer 160 may include any one of silicon dioxide (SiO₂), silicon nitride (Si₃N₄), magnesium oxide (MgO), zirconium oxide (ZrO₂),aluminum nitride (AIN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), and poly-silicon (p-Si), which are suitable for trimming a frequency. However, the protective layer 160 is limited thereto, and may be modified in various ways. For example, in order to increase the heat dissipation effect, the protective layer 160 may be formed of a diamond thin film.

The first electrode 121 and the second electrode 125 may extend outward of the resonating unit 120. In addition, a first metal layer 180 and a second metal layer 190 may be disposed on upper surfaces of the extending portions of the first electrode 121 and the second electrode 125, respectively.

Each of the first metal layer 180 and the second metal layer 190 may be formed of any one of gold (Au), a gold-tin (Au—Sn) alloy, copper (Cu), a copper-tin (Cu—Sn) alloy, aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may function as connection wirings electrically connecting the electrodes 121 and 125 of the acoustic resonator according to one or more embodiments to electrodes of another acoustic resonator disposed adjacent to the acoustic resonator according to one or more embodiments on the substrate 110.

The first metal layer 180 may be bonded to the first electrode 121, with at least a portion of the first metal layer 180 contacting the protective layer 160.

In addition, in the resonating unit 120, the first electrode 121 may be formed to have a larger area than the second electrode 125, and the first metal layer 180 may be formed along a circumferential portion of the first electrode 121. Therefore, the first metal layer 180 may be disposed along a circumference of the resonating unit 120, and may thus be disposed to surround the second electrode 125. However, the first metal layer 180 is not limited thereto.

Next, an acoustic wave resonator package according to one or more embodiments of the present disclosure will be described. The acoustic wave resonator package of one or more embodiments may refer to a device packaging the above-described acoustic resonator. Therefore, in addition to the above-described acoustic resonator, the acoustic wave resonator package of one or more embodiments may include a cover member for protecting the acoustic resonator.

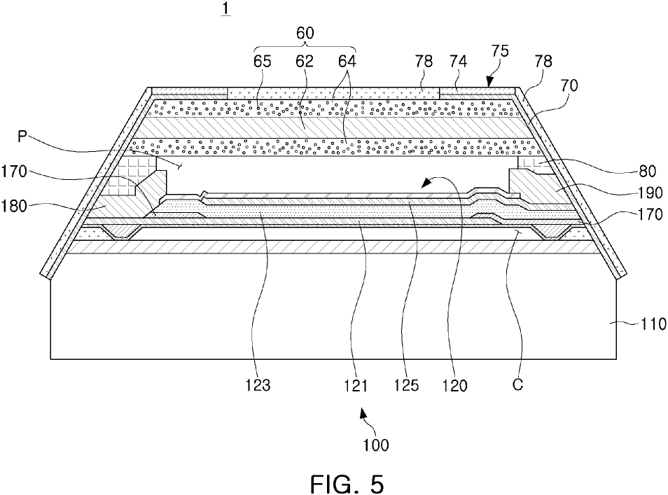

FIG. 5 is a schematic cross-sectional view illustrating an acoustic wave resonator package according to one or more embodiments of the present disclosure.

Referring to FIG. 5, the acoustic wave resonator package according to one or more embodiments may include a cover member 60 to protect the resonating unit 120 (or acoustic wave generator), from which an acoustic wave is generated, of the above-described acoustic resonator 100 from external environments.

The cover member 60, according to one or more embodiments, may include a core layer 62 and a resin layer 64 disposed on at least one surface of the core layer 62, and may be bonded to the acoustic resonator 100 through a bonding member 80.

The core layer 62 may be formed by impregnating a fiber base with a resin composition. The fiber base may include one or more selected from the group consisting of glass fiber, glass paper, glass web, glass cloth, aramid fiber, aramid paper, polyester fiber, carbon fiber, inorganic fiber, and organic fiber.

The core layer 62 may have a high modulus of 25 Gpa or more and a low coefficient of thermal expansion (CTE) of about 10 ppm/K. Thus, the core layer 62 may be provided with high rigidity.

The resin layer 64 may be disposed on one or both surfaces of the core layer 62.

The resin layer 64 may be formed together with the core layer 62 in the process of impregnating the fiber base with the resin composition and curing the resin composition. Thus, the resin layer 64 may be formed of the same material as the resin contained in the core layer 62. However, the cover is not limited thereto, and may be formed by manufacturing a core layer 62 and then stacking a resin layer 64 that is separately manufactured on the core layer 62. In this case, the resin layer 64 may be formed of a material different from the resin contained in the core layer 62.

The resin layer 64 may be formed of a thermosetting resin such as an epoxy resin, a polyimide resin, or a fluorine resin, but is not limited thereto.

Meanwhile, it may be considered to form a cover member 60 from only a polymer material without a core layer 62. In this case, however, the cover member 60 may have low rigidity, and as a result, the cover member 60 may be easily damaged by an internal pressure of molding applied through a sealing material in a process of sealing an acoustic wave resonator package 1 after being mounted on a mainboard.

However, in one or more embodiments, since the core layer 62 having high rigidity is included in the cover member 60, it is possible to prevent the cover member 60 from being deformed or damaged by the internal pressure of molding.

A filler 65 may be contained in the resin layer 64. The filler 65 may be formed in a particle or flake type, and may be provided to reduce a coefficient of thermal expansion of the resin layer 64. Thus, the filler 65 may be formed of a material having a lower coefficient of thermal expansion than the resin layer 64, e.g., an alumina or silica material.

In one or more embodiments, a side surface of the cover member 60 may be formed as an inclined surface. For example, with reference to FIG. 5, the side surface of the cover member 60 may be formed as an inclined surface forming an acute angle with a lower surface of the cover member 60. Here, the lower surface of the cover member 60 refers to a surface facing the acoustic resonator 100. Therefore, in one or more embodiments, the lower surface of the cover member 60 may have a larger area than the upper surface of the cover member 60.

Such a shape of the cover member 60 may be formed by a method of manufacturing the acoustic wave resonator package 1, which will be described below. This will be described in more detail in the manufacturing method to be described below. Meanwhile, it has been exemplified in one or more embodiments that the side surface of the cover member 60 is formed as a flat inclined surface. However, the side surface of the cover member 60 is not limited thereto, and may be formed as, for example, a curved surface or a plurality of irregular surfaces.

A wiring layer 70 and an external electrode 75 may be formed on surfaces of the cover member 60.

The wiring layer 70 may be connected to the electrodes 121 and 125 or the metal layers 180 and 190 of the acoustic resonator 100, and may be disposed in a conductive thin film type along the side surface, which is formed as an inclined surface, and the upper surface of the cover member 60.

In addition, at least a portion of the wiring layer 70 disposed on the upper surface of the cover member 60 may be formed as the external electrode 75. The external electrode 75 may be formed by stacking at least one plating layer 74 on the wiring layer 70, but is not limited thereto.

Solder balls or solder bumps may be bonded onto the external electrode 75. The solder balls or solder bumps may function as conductive bonding members for bonding the acoustic resonator 100 to the mainboard on which the acoustic wave resonator package 1 is mounted.

A plurality of external electrodes 75 may be disposed on the upper surface of the cover member 60, and may be electrically connected to the acoustic resonator 100 through the wiring layer 70 disposed along the side surface of the cover member 60.

In order to protect the wiring layer 70, an insulating protective layer 78 may be disposed on a surface of the wiring layer 70. The insulating layer 78 may be formed to entirely cover the wiring layer 70 except for the external electrode 75. The insulating layer 78 may also be disposed on a surface of the cover member 60 on which the wiring layer 70 is not formed.

The insulating layer 78 may be formed of an insulating resin such as photo resist, but is not limited thereto.

The cover member 60 may be bonded to the acoustic resonator 100 via the bonding member 80.

The bonding member 80 may be disposed to continuously surround the acoustic wave generator. Accordingly, an inner space P defined by the bonding member 80 and the cover member 60 may be formed as a sealed space.

The cover member 60 may be spaced apart from the acoustic resonator 100 by a predetermined distance with the bonding member 80 interposed therebetween.

The bonding member 80 may be formed of an insulating material such as resin or polymer, but is not limited thereto. If desired, the bonding member 80 may be formed of a metal material.

Meanwhile, at least some of the surfaces of the cover member 60 may have a surface roughness Rz in a range of 70 nm to 3.5 µm. For example, among the surfaces of the cover member 60, bonding surfaces to which the bonding member 80 and the wiring layer 70 are bonded may partially have the above-described roughness, and accordingly, the cover member 60 of one or more embodiments may be bonded to the bonding member 80 and wiring layer 70 with high bonding reliability. This will be described in more detail through the manufacturing method to be described below.

Next, a method of manufacturing the acoustic wave resonator package 1 described above will be described.

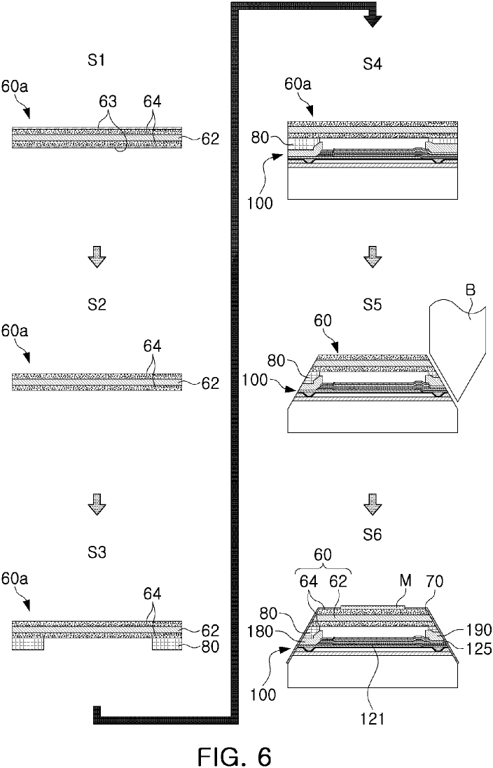

FIG. 6 is a view for explaining a method of manufacturing the acoustic wave resonator package illustrated in FIG. 5.

Referring to FIG. 6, in the method of manufacturing the acoustic wave resonator package 1 of one or more embodiments, first of all, a member 60a (hereinafter referred to as the panel member) used as a cover member 60 may be prepared (S1).

In the panel member 60a, resin layers 64 may be disposed on both surfaces of a core layer 62, and metal layers 63 may be stacked on surfaces of the resin layers 64. For example, the panel member 60a may be formed by impregnating glass fibers with resin to form a core layer 62 and resin layers 64, and stacking metal layers 63 on surfaces of the resin layers 64. Here, the resin layers 64 may be formed of a thermosetting resin such as an epoxy resin, a polyimide resin, or a fluorine resin, and the metal layers 63 may be formed of copper (Cu). The metal layers 63 may be thermo-compressed to be firmly bonded to the resin layers 64.

Subsequently, the metal layers 63 may be at least partially removed (S2). This operation may be performed through wet etching or dry etching.

Since the metal layers 63 is firmly bonded to the resin layer 64, when the metal layer 63 is removed in this operation, a roughness of the surface of the resin layer 64 to which the metal layer 63 was previously bonded may be greatly increased.

In one or more embodiments, the surface roughness of the resin layer 64 may vary depending on the material of the resin layer 64 or an etching method, but it was confirmed through various experiments that the resin layer 64, according to the above-described method, had a surface roughness Rz in a range of 70 nm to 3.5 µm.

Therefore, in one or more embodiments, the surface roughness Rz of the resin layer 64 may be in the range of 70 nm to 3.5 µm.

The increase in surface roughness of the resin layer 64 may increase the bonding strength between the cover member 60 and a bonding member 80 or a wiring layer 70 in a process of attaching the bonding member 80 to the surface of the cover member 60 or forming the wiring layer 70 on the surface of the cover member 60, which will be described below.

In general, in order to increase the surface roughness of a specific member, it is desired to perform additional surface treatment on a surface of the member. An example of the surface treatment may include plasma treatment. However, as a result of performing the plasma treatment on the resin layer 64 with no metal layer 63 stacked thereon for 10 minutes, it was confirmed that the surface roughness Rz of the resin layer 64 increased merely by about 50 nm to 60 nm. In this case, it is difficult to secure reliability in bonding the resin layer 64 with the bonding member 80 or the wiring layer 70 because the surface roughness of the resin layer 64 is very small.

On the other hand, when the metal layer 63 was stacked on the resin layer 64 in the process of manufacturing the panel member 60a and the metal layer 63 was removed from the panel member 60a later as in one or more embodiments, it was confirmed that the surface roughness Rz of the resin layer 64 was in the range of 70 nm to 3.5 µm, indicating a great increase in roughness. As a result, it was confirmed that the bonding strength was greatly increased.

Therefore, in one or more embodiments, the surface roughness of the resin layer 64 may be secured in the aforementioned range by stacking the metal layer 63 on the resin layer 64 in the process of manufacturing the panel member 60a and thereafter removing the metal layer 63 from the panel member 60a.

Subsequently, the bonding member 80 may be bonded to the panel member 60a (S3). The bonding member 80 may be bonded to one surface of the panel member 60a, and may be formed in a continuous ring shape. Specifically, when the panel member 60a is bonded to the acoustic resonator 100, the bonding member 80 may be attached at a position to continuously surround the circumference of the resonating unit 120. In addition, the bonding member 80 may be attached to the surface of the resin layer 64 exposed by removing the metal layer 63 in the above-described operation.

As described above, since the surface roughness of the resin layer 64 has been increased, when the bonding member 80 is attached to the resin layer 64, the roughness of the resin layer 64 may increase bonding strength between the bonding member 80 and the resin layer 64 by virtue of the roughness of the resin layer 64, which causes a mechanical anchoring effect between the bonding member 80 and the resin layer 64. Accordingly, it is possible to prevent a bonding interface from being easily peeled off, thereby securing bonding reliability.

The bonding member 80 may be prepared in a liquid or gel type and cured after being applied to the cover member 60, but is not limited thereto. Meanwhile, although it has been exemplified in one or more embodiments that the bonding member 80 is bonded to the panel member 60a, the configuration of the present disclosure is not limited thereto, and the bonding member 80 may be bonded to the acoustic resonator 100 first if desired.

Subsequently, the panel member 60a and the acoustic resonator 100 may be combined with each other (S4). The acoustic resonator 100 may be manufactured separately from the panel member 60a.

In this operation, the panel member 60a may be bonded to the acoustic resonator 100 via the bonding member 80. At this time, the panel member 60a and the acoustic resonator 100 may be spaced apart from each other by a predetermined distance with the bonding member 80 interposed therebetween, rather than contacting each other.

As the panel member 60a is combined with the acoustic resonator 100, an inner space P defined by the bonding member 80 and the panel member 60a may be formed as a sealed space as described above.

Subsequently, a side surface of the panel member 60a may be partially removed using a cutting device B such as a sawing device (S5). Through this operation, the panel member 60a may be completed as a cover member 60 of which a side surface is an inclined surface.

The inclined surface of the cover member 60 may be formed at an inclination angle corresponding to a shape or a cutting direction of a blade of the cutting device B.

In this operation, the acoustic resonator 100 may also be partially removed by the cutting device B together with the panel member 60a. Thus, a side surface of the acoustic resonator 100 may be formed as an inclined surface having the same inclination angle as the side surface of the cover member 60. Also, the side of the acoustic resonator 100 may be disposed on the same plane as the side of the cover member 60.

Subsequently, a wiring layer 70 may be formed on the surface of the cover member 60 (S6). This operation may include forming a mask pattern M on the surface of the cover member 60, forming a wiring layer 70 in a region where the mask pattern M is not formed, and removing the mask pattern M. Thus, the wiring layer 70 may not be formed in a region where the mask pattern M is formed.

The wiring layer 70 may be formed through a plating process. However, the wiring layer 70 is not limited thereto. In addition, the wiring layer 70 may be formed on the side surface of the acoustic resonator 100 as well. Accordingly, the wiring layer 70 may be electrically and physically connected to the first electrode 121, the second electrode 125, the first metal layer 180, and the second metal layer 190 exposed to the side surface of the acoustic resonator 100.

As described above, since the surface roughness of the resin layer 64 has been increased, when the wiring layer 70 is formed on the resin layer 64, the roughness of the resin layer 64 may increase a mechanical anchoring effect between the wiring layer 70 and the resin layer 64. Thus, it is possible to increase bonding strength between the wiring layer 70 and the resin layer 64, thereby preventing a bonding interface from being easily peeled off.

Next, a plating layer 74 may be stacked on a region to be used as an external electrode 75 of the wiring layer 70, and an insulating protective layer 78 may be formed on the other region of the wiring layer 70, such that the acoustic wave resonator package 1 illustrated in FIG. 5 is completed.

Meanwhile, the panel member 60a of one or more embodiments may be manufactured to have a large area. Therefore, in the method of manufacturing the acoustic wave resonator package 1 of one or more embodiments, a plurality of acoustic wave resonator packages 1 may be manufactured in a lump by manufacturing a plurality of acoustic resonators 100 on a wafer, bonding the panel member 60a entirely covering one surface of the wafer to the wafer, and cutting the panel member 60a bonded with the wafer.

The acoustic wave resonator package 1 of one or more embodiments configured as described above may obviate the need for a high-price semiconductor wafer at the time of forming the cover member 60, it is possible to reduce manufacturing costs. In addition, the acoustic wave resonator package 1 may be manufactured in a very easy way by combining the cover member 60, which is manufactured separately, with the acoustic resonator 100, rather than sequentially stacking the elements in a build-up type.

In addition, since the surface roughness of the cover member 60 is increased in the process of manufacturing the cover member 60, it is possible to increase bonding strength between the cover member 60 and the wiring layer 70 and the bonding member 80, which are bonded to the surface of the cover member 60, thereby increasing bonding reliability.

In addition, since the core layer 62 is included in the cover member 60, it is possible to solve the weak rigidity problem of the polymer material, such that the cover member 60 is easily used in transfer molding.

The configuration of the present disclosure is not limited to the above-described embodiments, and may be modified in various manners.

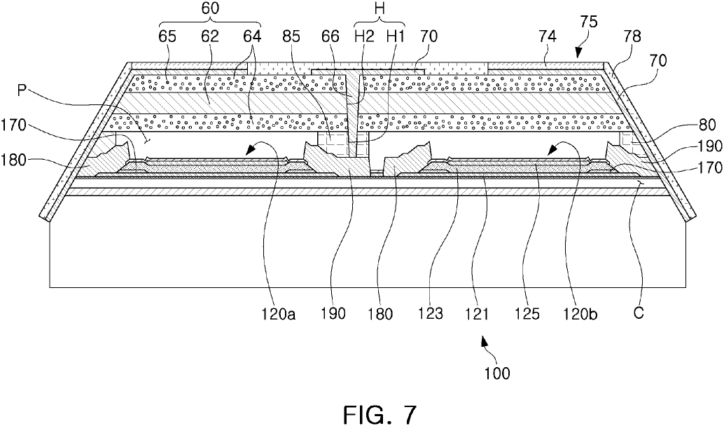

FIG. 7 is a schematic cross-sectional view illustrating another example of an acoustic wave resonator package according to one or more embodiments of the present disclosure.

Referring to FIG. 7, in the acoustic wave resonator package of one or more embodiments, at least two resonating units 120a and 120b may be disposed in the inner space P defined by the bonding member 80 and the cover member 60. In addition, the acoustic wave resonator package of one or more embodiments may include a through via 66 penetrating through the cover member 60.

The through via 66 may be formed to penetrate through the cover member 60 along a thickness direction of the cover member 60, and may extend toward the acoustic resonator 100 to be connected between the two resonating units 120a and 120b. In this case, one end of the through via 66 may be connected to either one or both of the two resonating units 120a and 120b. For example, one end of the through via 66 may be electrically connected to a first metal layer 180 or a second metal layer 190 of the resonating unit 120a or 120b.

A support member 85 may be disposed between the cover member 60 and the acoustic resonator 100 to form the through via 66. One surface of the support member 85 may be attached to the acoustic resonator 100, and the other surface of the support member 85 may be attached to the cover member 60. Then, the through via 66 may be connected to the acoustic resonator 100 by penetrating through the cover member 60 and the support member 85.

The support member 85 may be formed of the same material as the bonding member 80 described above. In this case, the support member 85 may be attached to the panel member 60a together with the bonding member 80 in the process of attaching the bonding member 80 to the panel member 60a. However, the configuration of the present disclosure is not limited thereto, and if desired, the support member 85 may be formed of a material different from that of the bonding member 80.

The method of manufacturing the acoustic wave resonator package of one or more embodiments configured as described above may further include, after the combining of the panel member 60a with the acoustic resonator 100 (S4 in FIG. 6), forming a through-hole H penetrating through the cover member 60 and the support member 85, and filling the through-hole H with a conductive material to form a through via 66.

Here, the filling of the through-hole H with the conductive material may be performed together at the time of the forming of the wiring layer 70 (S6) described above.

Meanwhile, the acoustic wave resonator package of one or more embodiments may be manufactured through a method other than the above-described manufacturing method.

For example, in the method of manufacturing the acoustic wave resonator package according to one or more embodiments, a through-hole H1 may be formed in the panel member 60a before the panel member 60a is bonded to the acoustic resonator 100. Specifically, after the removing of the metal layer 63 from the panel member 60a (S2 in FIG. 6), the through-hole H1 may be formed in the panel member 60a. Therefore, the support member 85 and the bonding member 80 may be attached to the panel member 60a after the through-hole H1 is formed in the panel member 60a.

Subsequently, after the combining of the panel member 60a with the acoustic resonator 100 (S4), a through-hole H2 may be additionally formed in the support member 85.

In this case, the through-hole H1 of the panel member 60a and the through-hole H2 of the support member 85 may have different diameters, but are not limited thereto.

Thereafter, the through via 66 may be completed by filling the through-hole H1 of the panel member 60a and the through-hole H2 of the support member 85 with a conductive material. As described above, the forming of the wiring layer 70 (S6) may include filling the through-holes H1 and H2 with a conductive material.

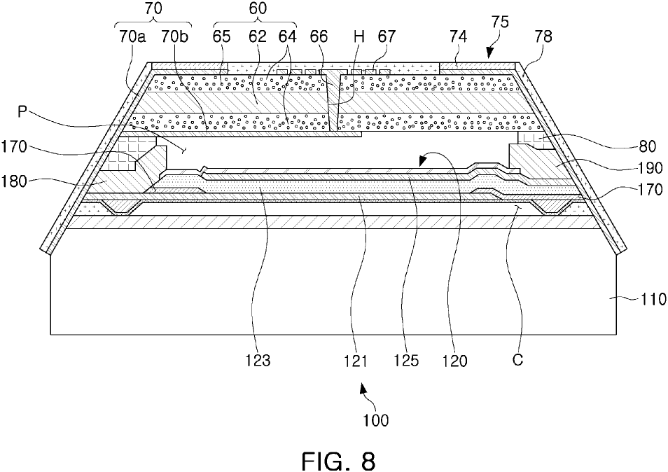

FIG. 8 is a schematic cross-sectional view illustrating another example of an acoustic wave resonator package according to one or more embodiments of the present disclosure.

Referring to FIG. 8, in the acoustic wave resonator package, according to one or more embodiments, at least one passive element 67 may be disposed on a surface of the cover member 60. In addition, the wiring layer 70 may include an outer wiring layer 70a disposed on an outer surface of the cover member 60 and an inner wiring layer 70a disposed on an inner surface (e.g., lower surface) of the cover member 60.

In one or more embodiments, the passive element 67 may be disposed on the upper surface of the cover member 60, and the passive element 67 may be connected to the inner wiring layer 70b formed on the lower surface of the cover member 60 through the through via 66.

The passive element 67 may include an inductor formed by the wiring layer 70. For example, the passive element 67 may be formed in a spiral pattern. However, the passive element 67 is not limited thereto, and may be formed in various shapes, such as a helical shape or a meander shape, as long as it is capable of providing inductance.

In addition, a plurality of passive elements 67 may be provided. In this case, the plurality of passive elements 67 may be connected to each other in parallel or in series.

The passive element 67 may be connected to the acoustic resonator 100. For example, the passive element 67 may be connected to the acoustic resonator 100 through the through via 66 and the inner wiring layer 70b. However, the passive element 67 is not limited thereto, and may be connected to the acoustic resonator 100 using only the outer wiring layer 70a without forming a through via 66.

In one or more embodiments, the inner wiring layer 70b may be formed as the metal layer 63 (see FIG. 6) prepared in the process of manufacturing the panel member 60a described above. For example, in the process of removing the metal layer 63, a partial portion of the metal layer 63 may be left for use as the inner wiring layer 70b, rather than removing all of the metal layer 63.

Meanwhile, although it has been exemplified in one or more embodiments that an inductor is provided as the passive element 67, a capacitor or a resistor may be provided in addition to the inductor.

In addition, the passive element 67 may be formed by patterning the metal layer 63 or the wiring layer 70. Thus, when the acoustic wave resonator package is manufactured, the passive element 67 may be formed by leaving a partial portion of the metal layer 63 in the process of removing the metal layer 63, or the passive element 67 may be formed together in the process of forming the wiring layer 70.

In addition, although it has been exemplified in one or more embodiments that the passive element 67 is disposed on the upper surface of the cover member 60, the passive element 67 may be disposed on the lower surface of the cover member 60 if desired. In this case, the passive element 67 may be formed at the time of the removing of the metal layer 63 (S2) described above.

In addition, since the support member 85 described above is not included in one or more embodiments, the through via 66 is formed only in the cover member 60. Thus, it is difficult to form a through via 66 in the cover member 60 after combining the panel member 60a with the acoustic resonator 100 (S4).

Therefore, the through via 66 of one or more embodiments may be formed in the process of manufacturing the panel member 60a. Specifically, the method of manufacturing the acoustic wave resonator package may further include, after the removing of the metal layer 63 (S2 in FIG. 6), forming a through-hole H penetrating through the panel member 60a, and filling the through-hole H with a conductive material to form a through via 66. Thereafter, the bonding member 80 may be bonded to the panel member 60a (S3).

As set forth above, according to one or more embodiments in the present disclosure, the acoustic wave resonator package has high bonding strength between the cover and the wiring layer and the bonding member, which are bonded to the surface of the cover, because the surface roughness of the cover is increased in the process of manufacturing the cover. As a result, it is possible to increase bonding reliability.

While the embodiments have been shown and described above, it will be apparent to those skilled in the art that modifications and variations could be made without departing from the scope of the present disclosure as defined by the appended claims.

For example, although it has been described that the above-described embodiments are applied to the bulk acoustic wave resonator, the above-described embodiments may also be applied to a surface acoustic wave resonator (SAWR).

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic wave resonator package comprising:
an acoustic resonator comprising an acoustic wave generator on a surface of a substrate;
a cover member disposed over the acoustic wave generator;
a bonding member, disposed between the substrate and the cover member, to bond the substrate and the cover member to each other; and
a wiring layer, disposed along surfaces of the cover member, connected to the acoustic resonator,
wherein, among the surfaces of the cover member, bonding surfaces to which the bonding member and the wiring layer are bonded at least partially have a roughness Rz in a range of 70 nm to 3.5 µm.

2. The acoustic wave resonator package of claim 1, wherein the cover member comprises a core layer, comprising glass fibers, and a resin layer disposed on either one or both opposing surfaces of the core layer.

3. The acoustic wave resonator package of claim 2, wherein the cover member comprises a filler in the resin layer, and
a coefficient of thermal expansion of the filler is lower than a coefficient of thermal expansion of the resin layer.

4. The acoustic wave resonator package of claim 3, wherein the filler is formed of an alumina or silica material.

5. The acoustic wave resonator package of claim 1, wherein a side surface of the cover member is inclined at an acute angle with a lower surface of the cover member.

6. The acoustic wave resonator package of claim 5, wherein the wiring layer is disposed along the side surface and an upper surface of the cover member.

7. The acoustic wave resonator package of claim 6, further comprising an external electrode formed on the wiring layer disposed on the upper surface of the cover member.

8. The acoustic wave resonator package of claim 1, further comprising a through via penetrating through the cover member,
wherein one end of the through via is electrically connected to the acoustic resonator.

9. The acoustic wave resonator package of claim 8, further comprising a passive element, disposed on a surface of the cover member, connected to the through via.

10. The acoustic wave resonator package of claim 9, wherein the passive element is formed by patterning a partial portion of the wiring layer.

11. The acoustic wave resonator package of claim 8, further comprising a support member disposed between the cover member and the acoustic resonator,
wherein the through via is connected to the acoustic resonator by penetrating through the support member.

12. A method of manufacturing an acoustic wave resonator package, the method comprising:
preparing a panel member comprising resin layers disposed on opposing surfaces of a core layer, and metal layers stacked on surfaces of the resin layers;
partially removing the metal layers from the panel member and increasing surface roughness of the panel member;
bonding the panel member to an acoustic resonator using a bonding member; and
forming a wiring layer on a surface of the panel member.

13. The method of claim 12, wherein the metal layers are removed through an etching process.

14. The method of claim 12, further comprising cutting the panel member to form a cover member, after the bonding of the panel member to the acoustic resonator using the bonding member,
wherein a side surface of the cover member is formed as an inclined surface during the cutting of the panel member.

15. The method of claim 12, further comprising forming a through-hole in the panel member, before the forming of the wiring layer,
wherein the forming of the wiring layer comprises filling the through-hole with a conductive material.

16. The method of claim 12, wherein the forming of the wiring layer further comprises patterning a partial portion of the wiring layer to form a passive element.

17. The method of claim 12, wherein the surface roughness of the panel member is increased to a range between 70 nm to 3.5 µm.
